(19) United States
(12) Patent Application Publication
(10) Pub. No.: US 2026/0305210 A1
(43) Pub. Date: Oct. 1, 2026

(54) RETICLE LAYOUT WITH PLASMA-ETCH WAFER DICING

(71) Applicants: Martin WEISS, Portland, OR (US); Kirsten THOMPSON, Hillsboro, OR (US); Abhishek JHALANI, Chandler, AZ (US); Edward MCKENNA, Portland, OR (US)

(72) Inventors: Martin WEISS, Portland, OR (US); Kirsten THOMPSON, Hillsboro, OR (US); Abhishek JHALANI, Chandler, AZ (US); Edward MCKENNA, Portland, OR (US)

(21) Appl. No.: 19/094,894

(22) Filed: Mar. 29, 2025

(51) Int. Cl. H01L 21/78; G03F 1/38

(52) U.S. Cl. CPC H10P 54/00; G03F 1/38

(57) ABSTRACT

Semiconductor reticles are provided with one or more die clusters. The dies in a die cluster may be separated with metal free cut zones, while scribe line regions may be disposed outside of and/or between the reticle die clusters.

### TECHNICAL FIELD

Embodiments relate generally to semiconductor wafer die singulation and layout configurations for facilitating the same.

### BRIEF DESCRIPTION OF THE DRAWINGS

The disclosure may best be understood by referring to the following description and accompanying drawings that are used to illustrate embodiments of the invention. In the drawings:

FIG. 1 is a diagram showing an exemplary semiconductor wafer.

FIG. 2 is a diagram showing a conventional reticle layout used for plasma etch dicing processes.

FIG. 3 is a diagram showing a reticle layout using a single cut-line separation approach in accordance with some embodiments.

FIG. 4 is a diagram showing a reticle layout with differently configured clusters in accordance with some embodiments.

FIG. 5 is a diagram showing a reticle layout illustrating differently shaped and sized scribe line regions in accordance with some embodiments.

FIG. 6 is a diagram showing a reticle layout in accordance with additional embodiments.

FIG. 7 is a diagram showing another scribe line and die cluster configuration in accordance with yet additional embodiments.

FIG. 8 is a diagram illustrating a heterogeneous reticle layout in accordance with some embodiments.

FIG. 9 is a flow diagram showing a routine for making an integrated circuit product in accordance with some embodiments.

### DETAILED DESCRIPTION

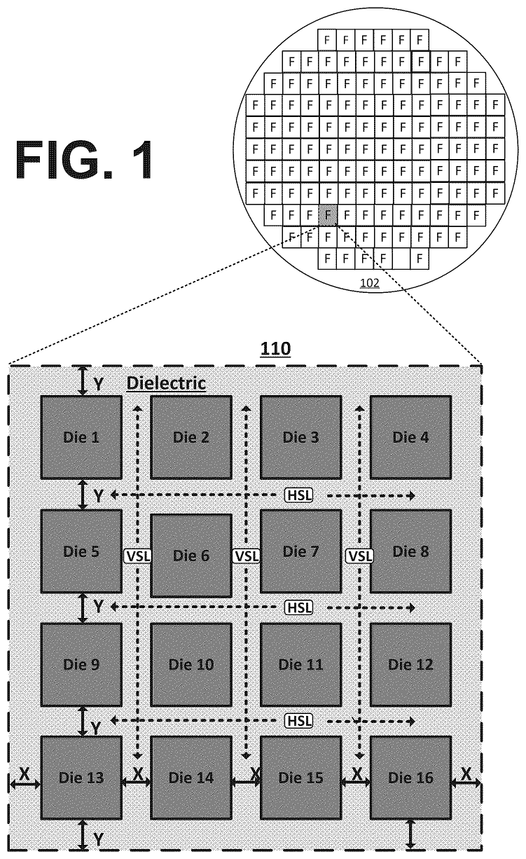

FIG. 1 is a diagram showing an exemplary semiconductor wafer 102. The wafer includes a plurality of arrayed fields (F) that each include one or more integrated circuit (IC) dies prior to being extracted from the wafer and packaged. For example, a step and scan process may be used with photo lithographic reticles (masks) to scan field patterns, one field at a time, onto the wafer. This is repeated for the various different layers that make up the integrated circuits.

The fields may be the same or different, e.g., if different reticles are applied. In addition, the fields could be of any suitable sizes. With some examples, a 300 mm (diameter) wafer may be used with reticle fields that are around 26 by 33 mm.

The figure shows an enlarged, representative view 110 of one of the fields. It illustrates how each field may include a plurality of dies. With this example, there are 16 equally sized dies that are separated from each other by dielectric material that corresponds to scribe line regions. As shown in the figure, there are vertically-aligned scribe lines (VSL) and horizontally-aligned scribe lines (HSL). The dies are arranged in an array with scribe lines in the same directions having the same widths. All of the vertical scribe lines have a width of X, and all of the horizontal scribe lines have a width of Y. For high volume manufacturing (HVM), it is typical for die patterns in the reticle to be copied multiple times across the reticle, forming a uniformly spaced array, as is shown.

When wafer fabrication is complete, the individual dies are singulated (also referred to as diced), with conventional approaches using wafer saw and laser ablation methods to cut through the scribe lines. Reticle layouts are generally designed around the limitations of the wafer saw process and associated reliability concerns, which include enabling the wafer saw to make cuts in straight lines and leaving a minimum required residual silicon around the final die to ensure cracks do not propagate into the active die.

Conventional reticles designed for die singulation by wafer saw and/or laser ablation typically use scribe lines with a fixed width in each direction (X, Y), which leads to excess scribe area on small die products and adversely affects wafer cost. Typical scribe line minimum widths are around 60 um. All scribe lines in a given direction are usually forced to have the same widths to reduce the complexity of the singulation process.

The various metrology structures (e.g., scanner marks, alignment marks, e-test structures, etc.) needed for wafer fabrication processes are disposed in the scribe lines. The amounts and types of metrology structures that are needed for a given design typically determine the minimum required scribe area that is needed for a reticle layout. Thus, a common approach for maximizing printable die/wafer is to minimize the total amount of metrology marks and thus keep scribe widths as narrow as possible. However, this approach is normally ineffective for products with small die areas (e.g., less than 100 mm²).

Since scribe width is also constrained by the fact that laser/saw singulation techniques are to be uniform in a given direction, the total scribe area for small die products grows rapidly with the number of dies and reticles and usually greatly exceeds the area required for metrology. The extra scribe area above and beyond the metrology requirement is effectively wasted (i.e. neither used for metrology nor active die area). Accordingly, new approaches would be desired.

Plasma dicing is a semiconductor manufacturing technique that uses chemical etching with ionized gas (plasma) to separate individual dies from a wafer. With this method, dicing streets (spaces between dies where cuts are to occur) are defined using a protective mask patterned onto the wafer with a suitable photo-lithographic process. For example, this can be a photoresist layer applied via lithography or achieved using existing passivation layers modified during device fabrication. In some embodiments, hybrid approaches may be employed, where lasers are used to first groove the wafer to create initial trenches to enhance the plasma etching step. With current processes for plasma-etch cutting, the cut streets (or areas) should be metal free for the etch process to effectively work.

When etching is to occur, the wafer is typically mounted onto a tape frame to maintain structural integrity during the etching. The wafer is placed in a vacuum chamber where reactive gases (e.g., SF₆, C₄F₈) are ionized into plasma using an electric field. For purposes of this disclosure, any suitable process, e.g., a Bosch process used for deep reactive ion etching may be used. Such processes may include repeating cycles of etching and passivation, creating reasonably vertical sidewalls (cuts where the protective mask is not present) with minimal lateral damage. The plasma chemically reacts with exposed silicon in the metal free (MF) cut zones (dicing streets), converting it into byproducts that are removed from the plasma ablation chamber. From here, the protective mask may be dissolved, leaving singulated dies on the tape for pickup.

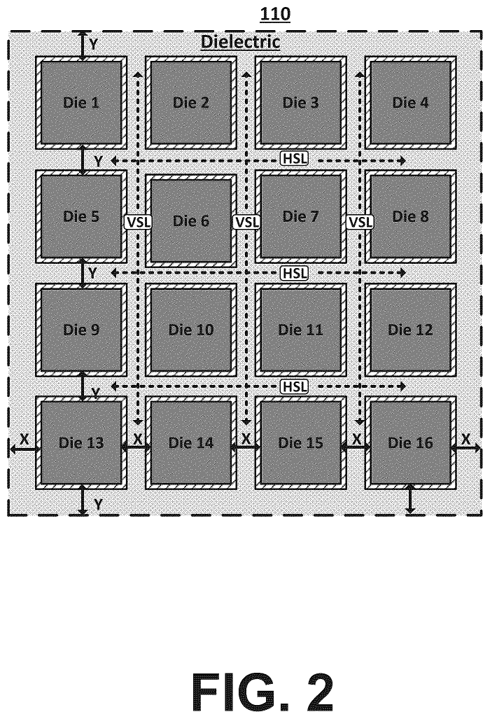

FIG. 2 is a diagram showing a conventional reticle layout used for plasma etch dicing processes. The reticle includes 16 equally sized dies (Die 1-Die 16), with each die surrounded by a metal free cut zone, typically 10-30 um wide and separated by scribe lines (e.g., greater than or equal to 60 um in width) from adjacent dies. This corresponds to 80-120 um of separation between adjacent dies on a reticle, still wasting a lot of useable wafer real estate.

In some embodiments, plasma dicing techniques may be used to reduce the amounts of needed scribe line area, leaving more of a wafer available for active die circuitry. Among other things, this can be achieved with the requirements imposed by traditional saw processes being removed. For example, no longer must scribe lines facilitate straight-line cuts and the preservation of residual silicon around the singulated dies to avoid reliability issues due to crack propagation. In some embodiments, this can allow for variable width scribe lines and reduced minimum distances between dies in a reticle layout. Moreover, it can provide added design flexibility for tailoring scribe widths to be optimized to the minimum area required by metrology and hence increase the total number of dies that can be printed on a given wafer.

In some embodiments, dies may be disposed adjacent to other dies in a reticle layout, separated by a single metal free zone. Some embodiments may also provide for variable width scribes that enable the scribe area to be tuned for the minimum area required by metrology.

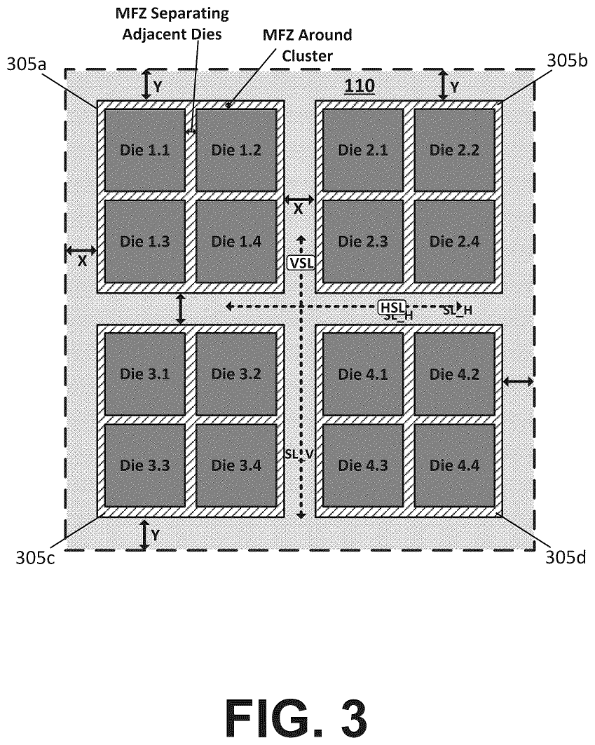

FIG. 3 is a diagram showing a reticle layout using a single cut-line separation approach in accordance with some embodiments. In this example, 16 dies are arranged into four equally sized clusters (or groups). The depicted four clusters include 305a (Dies 1.1-1.4), 305b (Dies 2.1-2.4), 305c (Dies 3.1-3.4), and 305d (Dies 4.1-4.4). (Note that for convenience, a cluster may be referred to by the first number that designates the dies in its group. For example, cluster 305a may be referred to as cluster 1, and cluster 305c may be referred to as cluster 3.)

The clusters themselves are separated by scribe line (SL) regions. (Note that for this disclosure, the diagonally-patterned shapes connote MFZ cutline locations, while the light gray-shaded areas correspond to areas where scribe line regions may occur and include metrology structures.) The layout includes horizontally-aligned scribe line regions having widths Y and vertically-aligned scribe line regions having widths X.

Each of a cluster's dies are separated by a single, narrow MF (metal free) cut zone cutline, with each cluster also surrounded by a relatively narrow MFZ cutline. This approach is particularly beneficial on products with small die sizes as it allows excess scribe line area to be eliminated while retaining scribe line regions needed for metrology.

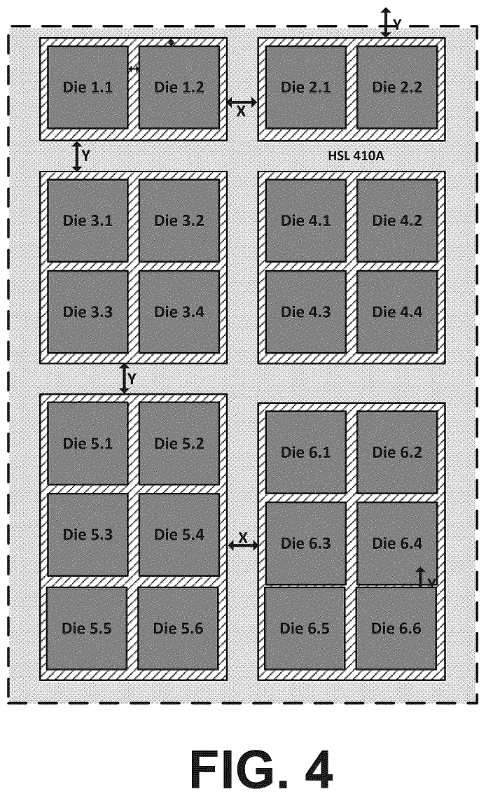

FIG. 4 is a diagram showing a reticle layout with differently configured clusters in accordance with some embodiments. As is shown, clusters 1, 2 each have two dies, clusters 3, 4 each have 4 dies, and clusters 5, 6 each have six dies. This example illustrates how a given reticle can contain multiple clusters with different numbers of dice per cluster. This can provide flexibility for optimizing scribe line locations as needed to best suit particular metrology needs.

The previous embodiments employed traditional, uniform-width scribe line approaches where all of the scribe lines in a given direction have a fixed width, i.e. all horizontal scribes have a width of Y and all vertical scribes have a width of X. Since plasma dicing can avoid the mechanical limitations of traditional wafer saw processes, new approaches may be utilized. Reticle layouts can have a variety of different widths for the individual horizontal and vertical scribe regions. The following examples illustrate different ways in which this may be achieved.

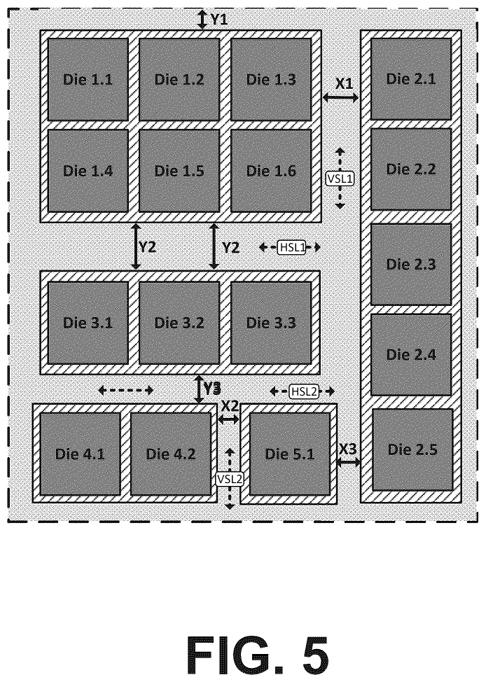

FIG. 5 is a diagram showing a reticle layout illustrating differently shaped and sized scribe line regions in accordance with some embodiments. There are vertically tending SL regions (VSL1-VSL3) and horizontally tending regions (HSL1, HSL2). The layout also includes different clusters (cluster 1-cluster 5) that have different numbers of dies and are shaped differently. Some are configured horizontally (clusters 1, 3, 4), while another (cluster 2) is vertically configured.

This layout demonstrates how Individual dies and die clusters can be freely arranged within a reticle layout, which allows for the use of variable widths and shapes for the horizontal and vertical scribes. This example also shows how dead-end scribe line regions (HSL1, HSL2) may be used. A dead-end scribe line region is a scribe line region that extends into a die cluster. With traditional sawing methods, such scribe lines could not exist. Thus, it can be seen that variable width and/or shape scribe line regions can provide flexibility to create scribe area specific locations that are best suited for metrology without inflating the overall scribe area. The combination of variable width scribes in conjunction with MF cut zone separated die clusters provides enhanced flexibility to optimize scribe area to meet metrology requirements while conserving total scribe area, which can be valuable since metrology structures for overlay and CD (critical dimension) measurements typically consume most of the area in the outermost scribe lines of a reticle layout.

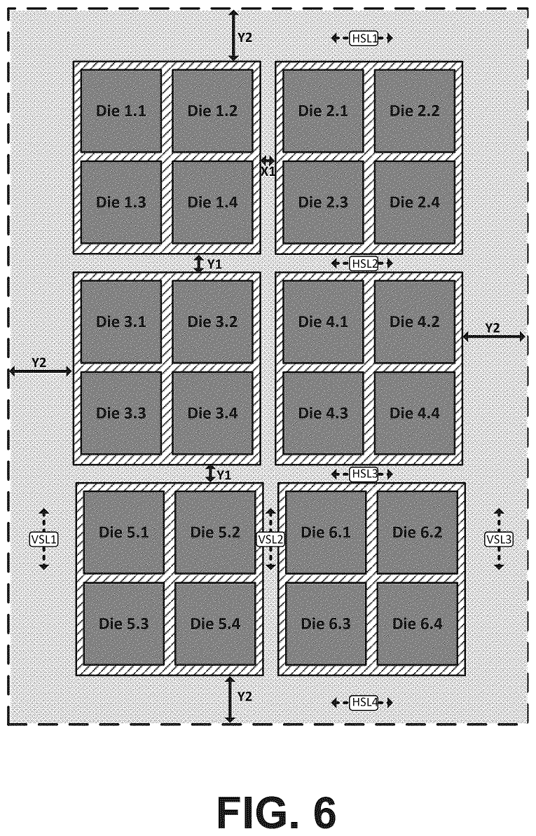

FIG. 6 is a diagram showing a reticle layout in accordance with additional embodiments. With this example, the general concepts presented in FIGS. 3-5 may be combined to create a layout such as is shown in FIG. 6 with wider exterior scribes, narrower interior scribes, and unneeded scribes between some of the dies eliminated through the use of MF cut zone separation.

The layout includes inner scribe line regions (HSL2, HSL3, VSL2) that may be narrow, as compared with outer SL regions (VSL1, VSL3, HSL1, HSL4). Such configurations can take advantage of the fact that as previously mentioned, many metrology structures (e.g., for overlay and CD measurements) typically require large amounts of space in a reticle's exterior scribe regions. Variable width scribes allow the reticle layout to be designed with larger exterior scribes and smaller interior scribes. For example, the outer scribe regions may be two or more times wider than the inner regions, and remaining scribe area not needed for metrology can be eliminated by placing dies adjacent to other dies, separated by MF cut zones, as is shown.

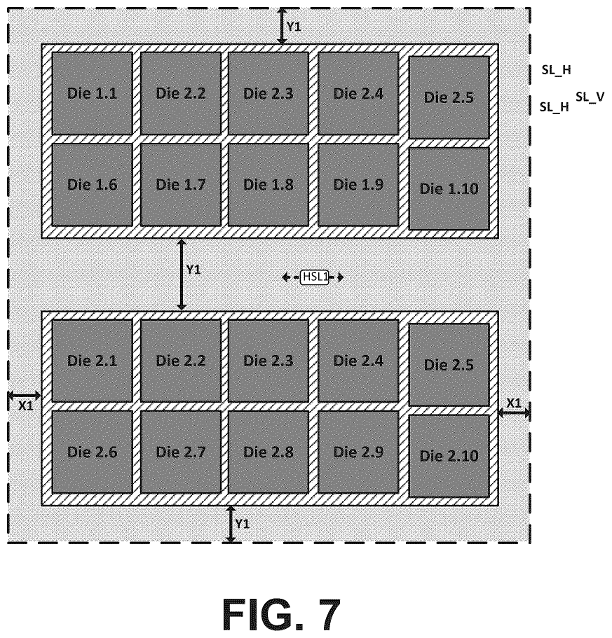

FIG. 7 is a diagram showing another scribe line and die cluster configuration in accordance with yet additional embodiments. With this example, an enlarged inner horizontal scribe line region (HSL1) is employed.

Variable width scribes allow for the creation of a large scribe area at specific locations in the reticle layout as needed for metrology purposes, for example a large layout that combines e-test with other in-line fab metrology structures. In this example, in contrast with the previous example, the inner SL region(s) is wider than its outer counterparts. This illustrates how plasma dicing can eliminate the need for scribes in a given direction to be the same width, which saves the area that would otherwise be consumed by excess scribe line, e.g., if all horizontal scribes were forced to have equivalent widths.

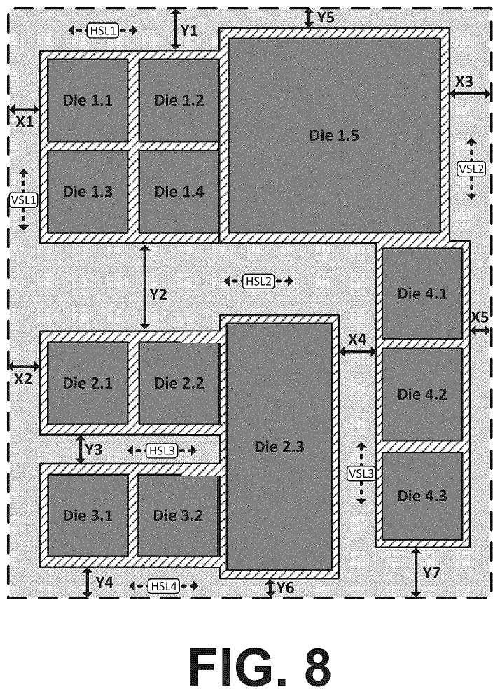

FIG. 8 is a diagram illustrating a heterogeneous reticle layout in accordance with some embodiments. A heterogenous layout is a layout that includes a mix of products with different die sizes.

The layout includes clusters (cluster 1, cluster 2) with differently sized dies, and it includes other clusters (cluster 3, cluster 4) with dies of the same dimensions. It also shows how a cluster can abut another cluster through a common MF cut zone. This is the case with clusters 2 and 3 where die 2.3 is separated by die 3.2 with a common MF cut zone.

The layout also includes a variety of differently sized and shaped SL regions. Here, there are horizontally tending SL regions with non-uniform widths (HSL1, HSL2, HSL4) and one with a uniform width (HSL3). Likewise, there are vertically aligned SL regions with uniform widths (VSL1) and non-uniform widths (VSL2, VSL3). Plasma dicing typically doesn't require die singulation along straight lines (unlike a wafer saw process), and thus, alignment of the edges of the various dies is not needed. All dies in the reticle layout can be harvested while simultaneously retaining the ability to minimize total scribe area.

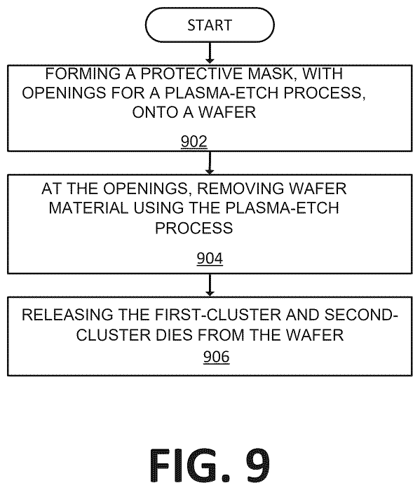

FIG. 9 is a flow diagram showing a routine for making an integrated circuit product in accordance with some embodiments. At 902, a protective mask is formed on a semiconductor wafer that has been fabricated to include a plurality of die clusters as discussed herein. The mask includes a pattern with openings for a plasma-etch process to remove material corresponding to the locations of the openings. The pattern conforms with a reticle layout that defined the die clusters. For example, the pattern may include a plurality of reticle fields, each field including at least a first cluster and a second cluster. The first cluster may include first-cluster dies and first-cluster metal-free (MF) cut zones surrounding the first cluster and separating the first-cluster dies.

Similarly, the second cluster may include second-cluster dies and second-cluster metal-free (MF) cut zones surrounding the second cluster and separating the second-cluster dies from one another. In some embodiments, the first and second clusters are separated from each other by at least one scribe line region that includes at least one metrology structure with the openings corresponding to the first-cluster and second-cluster metal free cut zones.

At 904, at the openings, the wafer material is removed using the plasma-etch process. At 906, the first-cluster and second-cluster dies may then be released from the wafer. From here, the released dies may be packaged into one or more integrated circuit package products such as a multi-chip processor package.

Illustrative examples of the technologies disclosed herein are provided below. An embodiment of the technologies may include any one or more, and any compatible combination of, the examples described below.

Example 1 is a semiconductor wafer apparatus that includes a first die cluster and a second die cluster. The first cluster includes first-cluster dies, and it also includes first-cluster metal-free (MF) cut zones surrounding the first cluster and separating the first-cluster dies from each other. The second cluster includes second-cluster dies and second-cluster metal-free (MF) cut zones surrounding the second cluster and separating the second-cluster dies from each other. The first and second clusters are separated by at least one scribe line region that includes at least one metrology structure.

Example 2 includes the subject matter of example 1, and wherein the first-cluster dies include dies with different geometric dimensions.

Example 3 includes the subject matter of any of examples 1-2, and wherein the first and second clusters are devoid of scribe line regions.

Example 4 includes the subject matter of any of examples 1-3, and wherein the at least one scribe line region includes two or more parallel-aligned scribe line regions with different widths.

Example 5 includes the subject matter of any of examples 1-4, and wherein the at least one scribe line region includes one or more dead-end scribe line regions.

Example 6 includes the subject matter of any of examples 1-5, and wherein first-cluster die sizes are different than second-cluster die sizes.

Example 7 includes the subject matter of any of examples 1-6, and wherein the first cluster has a first number of first-cluster dies, the second cluster has a second number of second-cluster dies, and the first and second numbers are different.

Example 8 includes the subject matter of any of examples 1-7, and wherein the first and second clusters are part of a first reticle field, the wafer apparatus including multiple instances of the first reticle field.

Example 9 is a process of making an integrated circuit (IC). The process includes forming a protective mask, with openings for a plasma-etch process, onto a wafer that includes a plurality of reticle fields. Each field includes: (i) a first cluster including first-cluster dies, the first cluster including first-cluster metal-free (MF) cut zones surrounding the first cluster and separating the first-cluster dies; and (ii) a second cluster including second-cluster dies, the second cluster including second-cluster metal-free (MF) cut zones surrounding the second cluster and separating the second-cluster dies, wherein the first and second clusters are separated by at least one scribe line region that includes at least one metrology structure, and wherein the openings correspond to the first-cluster and second-cluster metal free cut zones. The process also includes, at the openings, removing wafer material using the plasma-etch process, and then releasing the first-cluster and second-cluster dies from the wafer.

Example 10 includes the subject matter of example 9, and wherein the first-cluster dies include dies with different geometric dimensions.

Example 11 includes the subject matter of any of examples 9-10, and wherein the first and second clusters are devoid of scribe line regions.

Example 12 includes the subject matter of any of examples 9-11, and wherein the at least one scribe line region includes two or more parallel-aligned scribe line regions with different widths.

Example 13 includes the subject matter of any of examples 9-12, and wherein the at least one scribe line region includes one or more dead-end scribe line regions.

Example 14 includes the subject matter of any of examples 9-13, and wherein first-cluster die sizes are different than second-cluster die sizes.

Example 15 includes the subject matter of any of examples 9-14, and wherein the first cluster has a first number of first-cluster dies, the second cluster has a second number of second-cluster dies, and the first and second numbers are different.

Example 16 includes the subject matter of any of examples 9-15, and comprising packaging the first-cluster and second-cluster dies into a processor package.

Example 17 is a photo-lithography reticle mask apparatus for printing a reticle field onto a wafer. The mask apparatus defines a pattern comprising first and second die clusters. The first cluster includes first-cluster dies. The first cluster also includes first-cluster metal-free (MF) cut zones surrounding the first cluster and separating the first-cluster dies. The second cluster includes second-cluster dies. The second cluster also includes second-cluster metal-free (MF) cut zones surrounding the second cluster and separating the second-cluster dies. The first and second clusters are separated by at least one scribe line region that includes at least one metrology structure.

Example 18 includes the subject matter of example 17, and wherein the first-cluster dies include dies with different geometric dimensions.

Example 19 includes the subject matter of any of examples 17-18, and wherein the first and second clusters are devoid of scribe line regions.

Example 20 includes the subject matter of any of examples 17-19, and wherein the at least one scribe line region includes two or more parallel-aligned scribe line regions with different widths.

Example 21 includes the subject matter of any of examples 17-20, and wherein the at least one scribe line region includes one or more dead-end scribe line regions.

Example 22 includes the subject matter of any of examples 17-21, and wherein first-cluster die sizes are different than second-cluster die sizes.

Example 23 includes the subject matter of any of examples 17-22, and wherein the first cluster has a first number of first-cluster dies, the second cluster has a second number of second-cluster dies, and the first and second numbers are different.

Example 24 includes the subject matter of any of examples 17-23, and wherein the first and second clusters are part of a first reticle field, the wafer apparatus including multiple instances of the first reticle field.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. A semiconductor wafer apparatus, comprising:
a first cluster including first-cluster dies, the first cluster including first-cluster metal-free (MF) cut zones surrounding the first cluster and separating the first-cluster dies; and
a second cluster including second-cluster dies, the second cluster including second-cluster metal-free (MF) cut zones surrounding the second cluster and separating the second-cluster dies, wherein the first and second clusters are separated by at least one scribe line region that includes at least one metrology structure.

2. The apparatus of claim 1, wherein the first-cluster dies include dies with different geometric dimensions.

3. The apparatus of claim 1, wherein the first and second clusters are devoid of scribe line regions.

4. The apparatus of claim 1, wherein the at least one scribe line region includes two or more parallel-aligned scribe line regions with different widths.

5. The apparatus of claim 1, wherein the at least one scribe line region includes one or more dead-end scribe line regions.

6. The apparatus of claim 1, wherein first-cluster die sizes are different than second-cluster die sizes.

7. The apparatus of claim 1, wherein the first cluster has a first number of first-cluster dies, the second cluster has a second number of second-cluster dies, and the first and second numbers are different.

8. The apparatus of claim 1, wherein the first and second clusters are part of a first reticle field, the wafer apparatus including multiple instances of the first reticle field.

9. A process of making an integrated circuit (IC), comprising:
forming a protective mask, with openings for a plasma-etch process, onto a wafer that includes a plurality of reticle fields, each field including:
(i) a first cluster including first-cluster dies, the first cluster including first-cluster metal-free (MF) cut zones surrounding the first cluster and separating the first-cluster dies; and
(ii) a second cluster including second-cluster dies, the second cluster including second-cluster metal-free (MF) cut zones surrounding the second cluster and separating the second-cluster dies, wherein the first and second clusters are separated by at least one scribe line region that includes at least one metrology structure, and wherein the openings correspond to the first-cluster and second-cluster metal free cut zones;
at the openings, removing wafer material using the plasma-etch process; and
releasing the first-cluster and second-cluster dies from the wafer.

10. The process of claim 9, wherein the first-cluster dies include dies with different geometric dimensions.

11. The process of claim 9, wherein the first and second clusters are devoid of scribe line regions.

12. The process of claim 9, wherein the at least one scribe line region includes two or more parallel-aligned scribe line regions with different widths.

13. The process of claim 9, wherein the at least one scribe line region includes one or more dead-end scribe line regions.

14. The process of claim 9, wherein first-cluster die sizes are different than second-cluster die sizes.

15. The process of claim 9, wherein the first cluster has a first number of first-cluster dies, the second cluster has a second number of second-cluster dies, and the first and second numbers are different.

16. The process of claim 9, comprising packaging the first-cluster and second-cluster dies into a processor package.

17. A photo-lithography reticle mask apparatus for printing a reticle field onto a wafer, the mask apparatus defining a pattern comprising:
a first cluster including first-cluster dies, the first cluster including first-cluster metal-free (MF) cut zones surrounding the first cluster and separating the first-cluster dies; and
a second cluster including second-cluster dies, the second cluster including second-cluster metal-free (MF) cut zones surrounding the second cluster and separating the second-cluster dies, wherein the first and second clusters are separated by at least one scribe line region that includes at least one metrology structure.

18. The apparatus of claim 17, wherein the first-cluster dies include dies with different geometric dimensions.

19. The apparatus of claim 17, wherein the first and second clusters are devoid of scribe line regions.

20. The apparatus of claim 17, wherein the at least one scribe line region includes two or more parallel-aligned scribe line regions with different widths.
